(19) United States
(12) Patent Application Publication
(10) Pub. No.: US 2024/0164104 A1
(43) Pub. Date: May 16, 2024

(54) THREE-DIMENSIONAL FLASH MEMORY HAVING IMPROVED STACK CONNECTION PART AND METHOD FOR MANUFACTURING SAME

(71) Applicant: IUCF-HYU (Industry University Cooperation Foundation Hanyang University), Seoul (KR)

(72) Inventor: Yun Heub Song, Seoul (KR)

(73) Assignee: IUCF-HYU (Industry University Cooperation Foundation Hanyang University), Seoul (KR)

(21) Appl. No.: 18/552,625

(22) PCT Filed: Nov. 26, 2021
(86) PCT No.: PCT/KR2021/017623

§ 371 Date: Sep. 26, 2023

(30) Foreign Application Priority Data
Mar. 26, 2021 (KR) 10-2021-0039689

(51) Int. Cl. H10B 43/27; H10B 43/35; H10B 51/20; H10B 51/30

(52) U.S. Cl. CPC H10B 43/27; H10B 43/35; H10B 51/20; H10B 51/30

(57) ABSTRACT

Disclosed are a three-dimensional flash memory having an improved stack connection part and a method for manufacturing same. A three-dimensional flash memory according to an embodiment may comprise: multiple stack structures, each of which comprises multiple word lines alternately stacked in a vertical direction while extending in the horizontal direction, and at least one cell string extending through the multiple word lines in the vertical direction, the at least one cell string comprising a channel layer extending in the vertical direction and a charge storage layer formed to surround the channel layer; and at least one buffer layer that is disposed between the multiple stack structures stacked in the vertical direction and connects the channel layers of the multiple stack structures to each other.

### TECHNICAL FIELD

Following embodiments relate to a three-dimensional flash memory manufactured using a stack stacking process. More specifically, the following embodiments relate to a three-dimensional flash memory with an improved stack connection, and a manufacturing method thereof.

### BACKGROUND ART

A flash memory device is an electrically erasable programmable read only memory (EEPROM). The flash memory device may be commonly used, for example, in computers, digital cameras, MP3 players, gaming systems, and memory sticks, etc. The flash memory device electrically controls input and output of data under F-N tunneling (Fowler-Nordheimtunneling) or hot electron injection.

Specifically, referring to FIG. 1 showing an array of a conventional three-dimensional flash memory, the array of the three-dimensional flash memory may include a common source line CSL, a bit line BL, and a plurality of cell strings CSTR disposed between the common source line CSL and the bit line BL.

The bit lines are arranged two-dimensionally, and the plurality of cell strings CSTR are connected in parallel to each of the bit lines. The cell strings CSTR may be commonly connected to the common source line CSL. That is, the plurality of cell strings CSTR may be disposed between a plurality of bit lines and one common source line CSL. In this regard, there may be a plurality of common source lines CSL, and the plurality of common source lines CSL may be arranged two-dimensionally. In this regard, the same electrical voltage may be applied to the plurality of common source lines CSL, or each of the plurality of common source lines CSL may be electrically controlled.

Each of the cell strings CSTR may be composed of a ground select transistor GST connected to the common source line CSL, a string select transistor SST connected to the bit line BL, and a plurality of memory cell transistors MCT disposed between the ground and string select transistors GST and SST. Additionally, the ground select transistor GST, the string select transistor SST, and the memory cell transistors MCT may be connected in series with each other.

The common source line CSL may be commonly connected to sources of the ground select transistors GST. In addition, a ground select line GSL, a plurality of word lines WL0 to WL3, and a plurality of string select lines SSL disposed between the common source line CSL and the bit line BL may be used as electrode layers of the ground select transistor GST, the memory cell transistors MCT, and the string select transistors SST, respectively. Furthermore, each of the memory cell transistors MCT includes a memory element.

In the conventional three-dimensional flash memory, an integration is increasing by vertically stacking cells in order to meet excellent performance and a low price demanded by consumers.

For example, referring to FIG. 2 showing a structure of the conventional three-dimensional flash memory, the conventional three-dimensional flash memory is manufactured by disposing, on a substrate 200, an electrode structure 215 in which interlayer insulating layers 211 and horizontal structures 250 are alternately and repeatedly arranged with each other in a vertical manner. The interlayer insulating layers 211 and the horizontal structures 250 may extend in a first direction. Each of the interlayer insulating layers 211 may be, for example, a silicon oxide film, and the lowest interlayer insulating layer 211a among the interlayer insulating layers 211 may have a smaller thickness than that of each of the remaining interlayer insulating layers 211. Each of the horizontal structures 250 may include first and second blocking insulating films 242 and 243 and an electrode layer 245. A plurality of electrode structures 215 are provided. The plurality of electrode structures 215 may be arranged to face each other in a second direction intersecting the first direction. The first and second directions may correspond to an x-axis and a y-axis of FIG. 2, respectively. Between the plurality of electrode structures 215, trenches 240 spacing the plurality of electrode structures from each other may be disposed and may extend in the first direction. Highly doped impurity areas may be formed in areas of the substrate 200 respectively exposed through the trenches 240 and may act as the common source lines CSL. Although not shown, isolation insulating films that respectively fill the trenches 240 may be further disposed.

Vertical structures 230 extending through the electrode structure 215 may be disposed. In one example, the vertical structures 230 may be arranged along the first and second directions and thus may be arranged in a matrix form in a plan view. In another example, the vertical structures 230 may be arranged in a linear manner in the second direction and may be arranged in a zigzag shape in the first direction. Each of the vertical structures 230 may include a protective film 224, a charge storage film 225, a tunnel insulating film 226, and a channel layer 227. In one example, the channel layer 227 may be formed in a hollow tube shape, and in this case, a buried film 228 that fills a hollow space of the channel layer 227 may be further disposed. A drain area D may be disposed on a top of the channel layer 227, and a conductive pattern 229 may be formed on the drain area D, and may be connected to the bit line BL. The bit line BL may extend in a direction intersecting the horizontal electrodes 250, for example, in the second direction. In one example, the vertical structures 230 arranged in a line in the second direction may be connected to one bit line BL.

The first and second blocking insulating films 242 and 243 included in the horizontal structures 250 and the charge storage film 225 and the tunnel insulating film 226 included in the vertical structures 230 may be defined as ONO (Oxide-Nitride-Oxide) layers as information storage elements of the three-dimensional flash memory. That is, some of the information storage elements may be included in the vertical structures 230, and the others thereof may be included in the horizontal structures 250. In one example, among the information storage elements, the charge storage film 225 and the tunnel insulating film 226 may be included in the vertical structures 230, and the first and second blocking insulating films 242 and 243 may be included in the horizontal structures 250. However, the present disclosure is not limited or restricted thereto. The charge storage film 225 and the tunnel insulating film 226 which are defined as the ONO layers may be implemented to be included only in the vertical structures 230.

Epitaxial patterns 222 may be disposed between the substrate 200 and the vertical structures 230. The epitaxial patterns 222 connect the substrate 200 and the vertical structures 230 to each other. The epitaxial patterns 222 may contact the horizontal structures 250 of at least one layer. That is, the epitaxial patterns 222 may contact the lowermost horizontal structure 250a. According to another embodiment, the epitaxial patterns 222 may contact the horizontal structures 250 of a plurality of layers, for example, two layers. When the epitaxial patterns 222 contact the lowermost horizontal structure 250a, the lowermost horizontal structure 250a may be thicker than each of the remaining horizontal structures 250. The lowermost horizontal structure 250a in contact with the epitaxial patterns 222 may correspond to the ground select line GSL of the array of the three-dimensional flash memory described with reference to FIG. 1. The remaining horizontal structures 250 contacting the vertical structures 230 may correspond to the plurality of word lines WL0 to WL3.

Each of the epitaxial patterns 222 has a recessed side wall 222a. Accordingly, the lowermost horizontal structure 250a in contact with the epitaxial patterns 222 is disposed along a profile of the recessed side wall 222a. That is, the lowermost horizontal structure 250a may be formed in an inwardly convex shape and along the recessed side walls 222a of the epitaxial patterns 222.

The conventional three-dimensional flash memory with the above structure tends to be manufactured with an increased number of vertical stacks to improve vertical integration. For this purpose, a stack stacking process that stacks stack semiconductors has been proposed.

However, referring to FIG. 3 to illustrate problems of the three-dimensional flash memory manufactured through the conventional stack stacking process, the three-dimensional flash memory manufactured through the conventional stack stacking process has a poor connection problem in which a channel layer 311 of a lower stack structure 310 and a channel layer 321 of an upper stack structure 320 are not connected to each other properly due to misalignment of the stack structures 310 and 320.

Accordingly, a scheme to solve the above problem is required.

### DETAILED DESCRIPTION OF THE INVENTION

### Technical Problem

One embodiment proposes a three-dimensional flash memory with a structure including at least one buffer layer that connects channel layers of stack structures to each other to solve the problem of the poor connection, and a manufacturing method thereof.

However, the technical purposes that the present disclosure seeks to achieve are not limited to the above purposes, and may be expanded in various ways without departing from the technical idea and scope of the present disclosure.

### Technical Solution

According to one embodiment, a three-dimensional flash memory with an improved stack connection may include a plurality of stack structures, wherein each of the plurality of stack structures includes: a plurality of word lines extending in a horizontal direction and stacked alternately with each other in a vertical direction; and at least one cell string extending through the plurality of word lines in the vertical direction, wherein the at least one cell string includes a channel layer extending in the vertical direction and a charge storage layer formed to surround the channel layer; and at least one buffer layer disposed between adjacent ones of the plurality of stack structures arranged in the vertical direction, wherein the least one buffer layer connects the respective channel layers of the adjacent ones of the plurality of stack structures to each other.

According to one feature, the at least one buffer layer may have a size and a position set such that the at least one buffer layer accommodates both the respective channel layers of the adjacent ones of the plurality of stack structures in a plan view of the three-dimensional flash memory.

According to another feature, the at least one buffer layer may be made of the same material as a material constituting the respective channel layers of the adjacent ones of the plurality of stack structures.

According to one embodiment, a method for manufacturing a three-dimensional flash memory with an improved stack connection may include preparing a lower stack structure including: a plurality of word lines extending in a horizontal direction and stacked alternately with each other in a vertical direction; and at least one hole extending through the plurality of word lines in the vertical direction; forming a charge storage layer having an inner hole defined therein in the at least one hole of the lower stack structure; disposing at least one buffer layer on a top surface of the lower stack structure; forming an upper stack structure on top of the lower stack structure on which the at least one buffer layer has been disposed, wherein the upper stack structure including: a plurality of word lines extending in the horizontal direction and stacked alternately with each other in the vertical direction; and at least one hole extending through the plurality of word lines in the vertical direction; forming a charge storage layer having an inner hole defined therein in the at least one hole of the upper stack structure; removing a portion of the at least one buffer layer corresponding to the inner hole of each of the lower stack structure and the upper stack structure, wherein the inner hole of the lower stack structure and the inner hole of the upper stack structure communicate with each other by removing the portion of the at least one buffer layer; and forming a channel layer in an integrated manner in the respective inner holes of the lower stack structure and the upper stack structure.

According to another feature, the disposing of the at least one buffer layer may include forming the at least one buffer layer so as to have a size and a position set such that the at least one buffer layer accommodates both the respective inner holes of the lower stack structure and the upper stack structure in a plan view of the three-dimensional flash memory.

### Advantageous Effects of the Invention

One embodiment proposes the three-dimensional flash memory with a structure including the at least one buffer layer connecting the channel layers of the stack structures to each other and the manufacturing method thereof, thereby preventing the poor connection from occurring.

However, the effects of the present disclosure are not limited to the above effects, and may be expanded in various ways without departing from the technical idea and scope of the present disclosure.

### DESCRIPTION OF THE DRAWINGS

FIG. 1 is a simplified circuit diagram showing an array of a conventional three-dimensional flash memory.

FIG. 2 is a perspective view showing a structure of a conventional three-dimensional flash memory.

FIG. 3 is a diagram to illustrate the problem of a three-dimensional flash memory manufactured through a conventional stack stacking process.

FIG. 4 is a side cross-sectional view showing a three-dimensional flash memory according to an embodiment.

FIG. 5 is a side cross-sectional view briefly showing a portion of a three-dimensional flash memory to illustrate that a size and a position of at least one buffer layer are adjusted according to an embodiment.

FIG. 6 is a flowchart showing a manufacturing method of three-dimensional flash memory according to an embodiment.

FIGS. 7A to 7H are side cross-sectional views showing a three-dimensional flash memory to illustrate the manufacturing method of the three-dimensional flash memory as shown in FIG. 6.

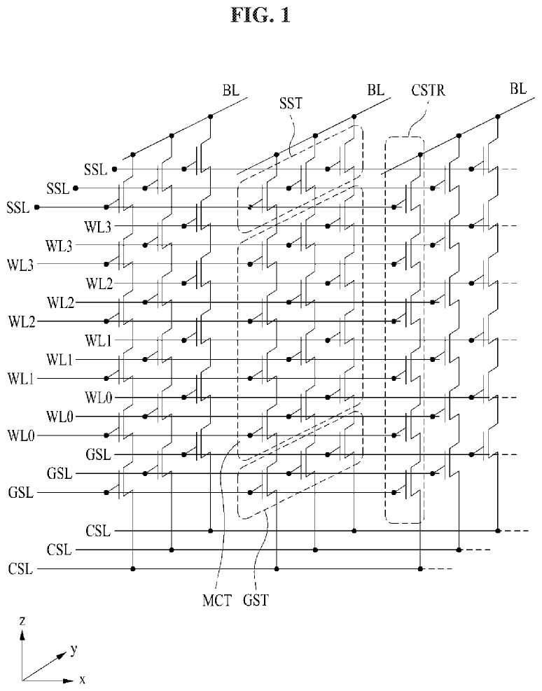

### BEST MODE

Hereinafter, embodiments of the present disclosure will be described in detail with reference to the attached drawings. However, the present disclosure is not limited or restricted by the embodiments. Furthermore, like reference numerals given in the drawings indicate like elements.

Furthermore, the terms (terminology) used herein are terms used to appropriately express preferred embodiments of the present disclosure, and may vary based on the viewer's, operator's intention, or customs of the field to which the present disclosure belongs. Therefore, definitions of these terms should be made based on the contents throughout the present disclosure. For example, in the present disclosure, the singular form includes the plural form unless specifically stated in the phrase. Furthermore, as used herein, “comprises” and/or “including” does not exclude the presence or addition of at least one component, step, operation and/or element other than a component, a step, an operation and/or an element as stated.

Furthermore, it should be understood that the various embodiments of the present disclosure are different from each other but are not necessarily mutually exclusive. For example, specific shapes, structures and characteristics as described with respect to one embodiment may be implemented in other embodiments without departing from the spirit and scope of the present disclosure. Furthermore, it should be understood that a location, an arrangement, or a configuration of an individual component in each presented embodiment may be changed without departing from the technical spirit and scope of the present disclosure.

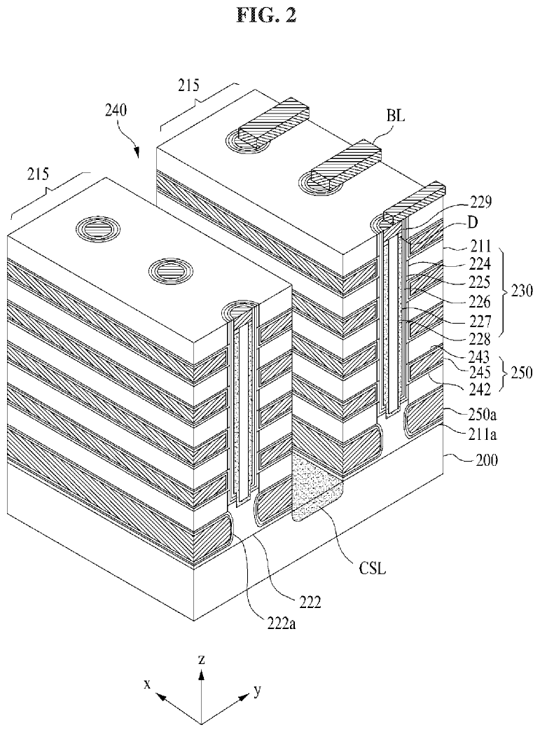

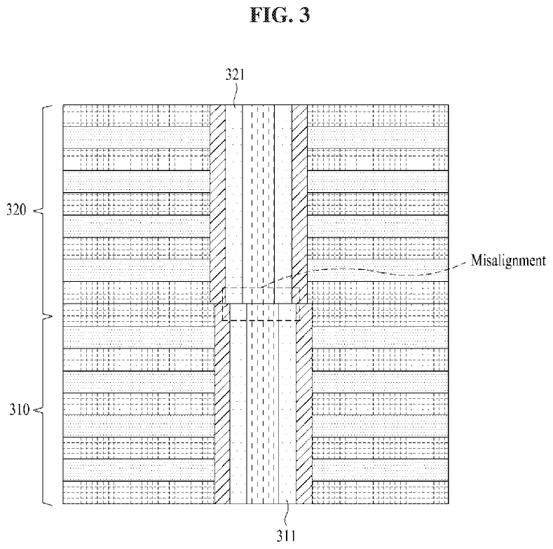

Hereinafter, in the side cross-sectional view showing the three-dimensional flash memory, the three-dimensional flash memory will be shown and described while a component such as a source line located under at least one cell string is omitted for convenience of illustration. However, the three-dimensional flash memory described later is not limited or restricted thereto and may include an additional component based on the structure of the conventional three-dimensional flash memory as shown with reference to FIG. 2.

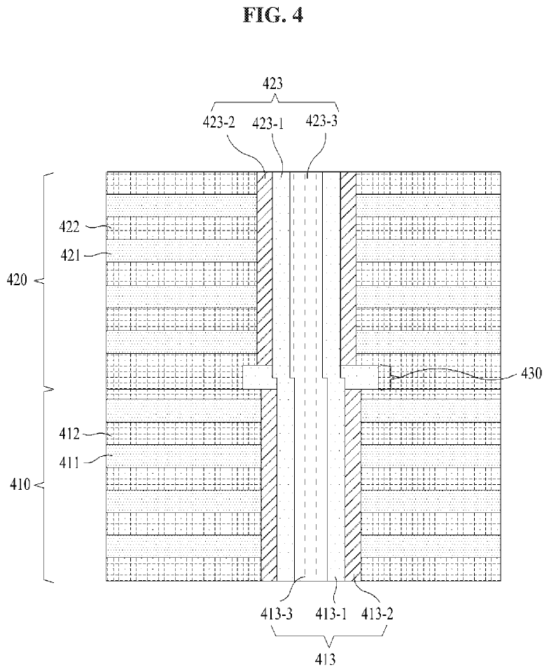

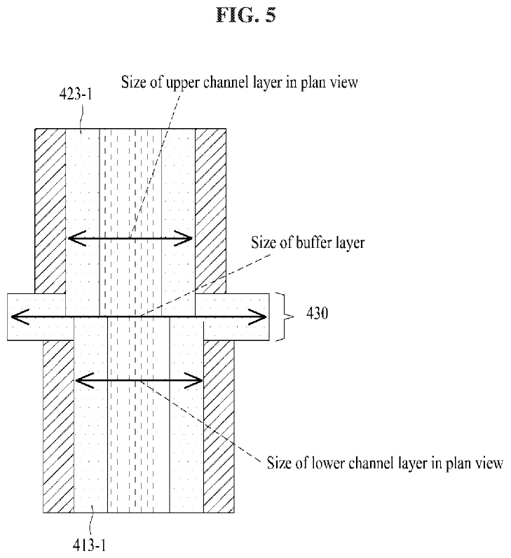

FIG. 4 is a side cross-sectional view showing a three-dimensional flash memory according to an embodiment. FIG. 5 is a side cross-sectional view briefly showing a portion of a three-dimensional flash memory to illustrate that a size and a position of at least one buffer layer are adjusted according to an embodiment.

Referring to FIG. 4, a three-dimensional flash memory 400 is manufactured through a stack stacking process, and thus may include a plurality of stack structures 410 and 420.

In this regard, each of the plurality of stack structures 410 and 420 may include a plurality of word lines 411 and 421, a plurality of interlayer insulating layers 412 and 422, and at least one cell string 413 and 423.

The plurality of word lines 411 and 421 included in each of the plurality of stack structures 410 and 420 may be sequentially stacked in a vertical direction while extending in a horizontal direction. Each of the plurality of 15 word lines 411 and 421 may be made of a conductive material such as W (tungsten), Ti (titanium), Ta (tantalum), Cu (copper), Mo (molybdenum), Ru (ruthenium), or Au (gold) (including all metal materials which can be deposited via ALD (atomic layer deposition) in addition to the above-described metal materials). The plurality of word lines 411 and 421 may respectively apply voltages to corresponding memory cells thereto to allow a memory operation (hereinafter, the memory operation includes a read operation, a program operation, and an erase operation) to be performed.

A string select line (SSL) (not shown) may be disposed on top of the plurality of word lines 411 and 421, and a ground select line (GSL) (not shown) may be disposed thereunder.

Each of the plurality of interlayer insulating layers 412 and 422 included in each of the plurality of stack structures 410 and 420 may extend horizontally while being disposed between the plurality of word lines 411 and 421, and may be made of an insulating material such as SiO₂ or Si₃N₄.

Accordingly, the plurality of word lines 411 and 421 and the plurality of interlayer insulating layers 412 and 422 may be alternately stacked with each other in the vertical direction in each of the plurality of stack structures 410 and 420.

The at least one cell string 413 and 423 included in each of the plurality of stack structures 410 and 420 may extend vertically through the plurality of word lines 411 and 421 and the plurality of interlayer insulating layers 412 and 422 and may include channel layers 413-1 and 423-1 and charge storage layers 413-2 and 423-2, and thus constitute a plurality of memory cells corresponding to the plurality of word lines 411 and 421.

The respective channel layers 413-1 and 423-1 of the plurality of stack structures 410 and 420 may extend in the vertical direction and may be made of single crystal silicon or poly-silicon, and may transfer electrons or holes to the charge storage layers 413-2 and 423-2 based on a voltage applied through the plurality of word lines 411 and 421, the SSL, the GSL, and the bit lines. As the channel layers 413-1 and 423-1 is formed of a hollow macaroni shape, the channel layers 413-1 and 423-1 may respectively contain buried films 413-3 and 423-3 made of an oxide therein.

The respective charge storage layers 413-2 and 423-2 of the plurality of stack structures 410 and 420 may extend to surround the channel layers 413-1 and 423-1, respectively, and may trap electrons or holes or maintain a state of the charges (e.g., a polarization state of the charges) based on a voltage applied through the plurality of word lines 411 and 421. Each of the charge storage layers 413-2 and 423-2 may be divided into areas corresponding to the plurality of word lines 411 and 421. The charge storage layers 413-2 and 423-2 together with the channel layers 413-1 and 423-1 may constitute the plurality of memory cells to serve as data storage in the three-dimensional flash memory 400. In one example, an ONO (Oxide-Nitride-Oxide) layer or a ferroelectric layer may be used as the charge storage layers 413-2 and 423-2. The charge storage layers 413-2 and 423-2 are not limited or restricted to a configuration that the charge storage layers 413-2 and 423-2 extend so as to surround the channel layers 413-1 and 423-1, respectively. The charge storage layers 413-2 and 423-2 may surround the channel layers 413-1 and 423-1, respectively and each of the charge storage layers 413-2 and 423-2 may be divided into areas corresponding to the memory cells.

The three-dimensional flash memory 400 of the above structure may include at least one buffer layer 430 which is disposed between the plurality of stack structures 410 and 420 stacked in the vertical direction and connects the respective channel layers 413-1 and 423-1 of the plurality of stack structures 410 and 420 to each other. Hereinafter, connecting the channel layers 413-1 and 423-1 of the plurality of stack structures 410 and 420 to each other means not only physically connecting the respective channel layers 413-1 and 423-1 of the plurality of stack structures 410 and 420 to each other, but also electrically connecting the respective channel layers 413-1 and 423-1 of the plurality of stack structures 410 and 420 to each other.

In this regard, the at least one buffer layer 430 may have a size and a position set such that the at least one buffer layer 430 accommodates the respective channel layers 413-1 and 423-1 of the plurality of stack structures 410 and 420 in a plan view. For example, in order to connect the channel layer 413-1 of the lower stack structure 410 and the channel layer 423-1 of the upper stack structure 420 to each other, the at least one buffer layer 430 may have a size and a position set such that the at least one buffer layer 430 accommodates both the channel layer 413-1 of the lower stack structure 410 and the channel layer 423-1 of the upper stack structure 420 in a plan view as shown in FIG. 5. That is, the at least one buffer layer 430 may have a size and a position set such that the at least one buffer layer 430 contacts both the channel layer 413-1 of the lower stack structure 410 and the channel layer 423-1 of the upper stack structure 420.

Furthermore, in order to electrically connect the channel layer 413-1 of the lower stack structure 410 and the channel layer 423-1 of the upper stack structure 420 to each other, the at least one buffer layer 430 may be made of the same material as that of the respective channel layers 413-1 and 423-1 of the plurality of stack structures 410 and 420.

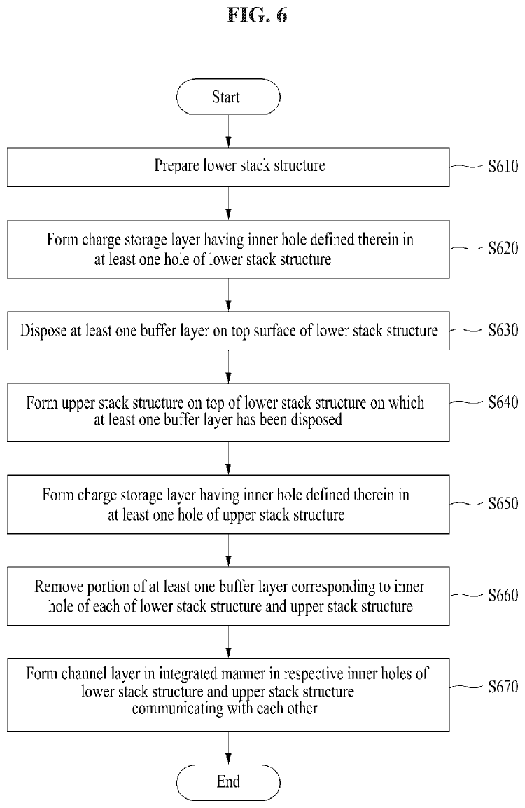

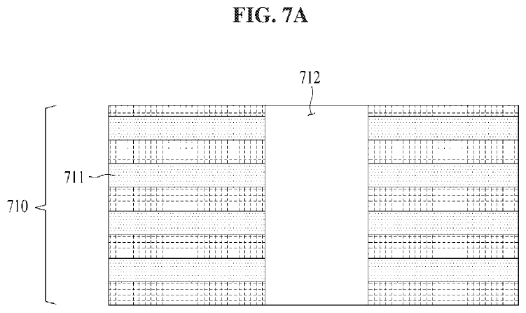

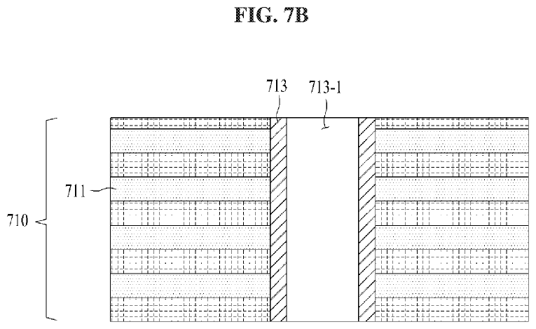

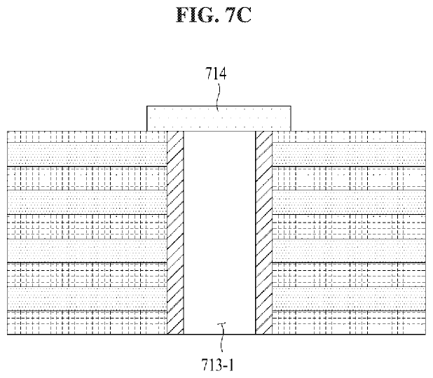

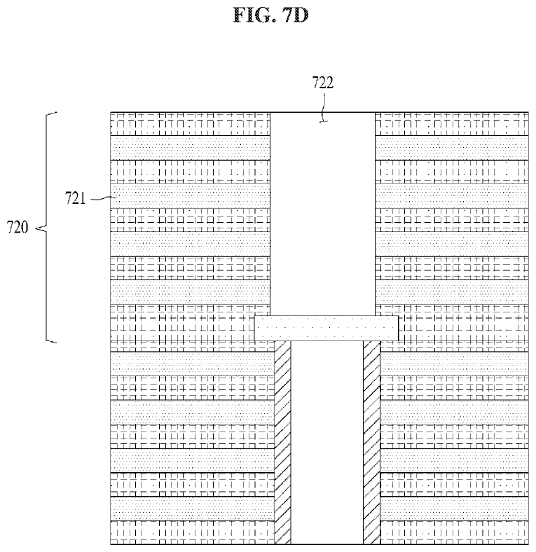

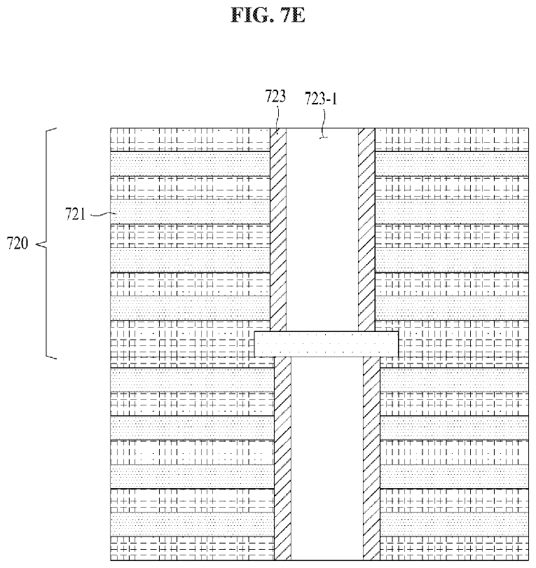

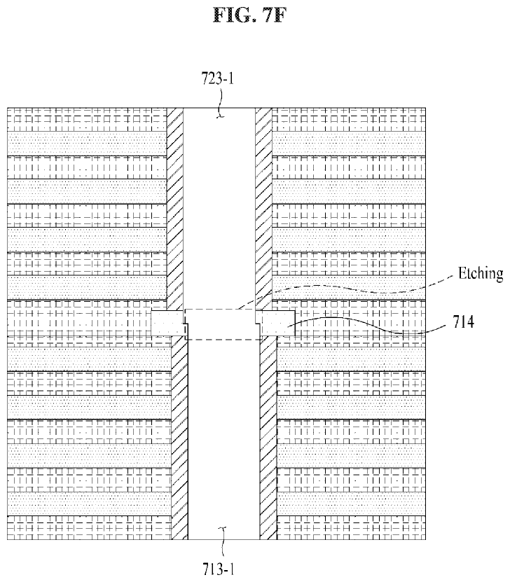

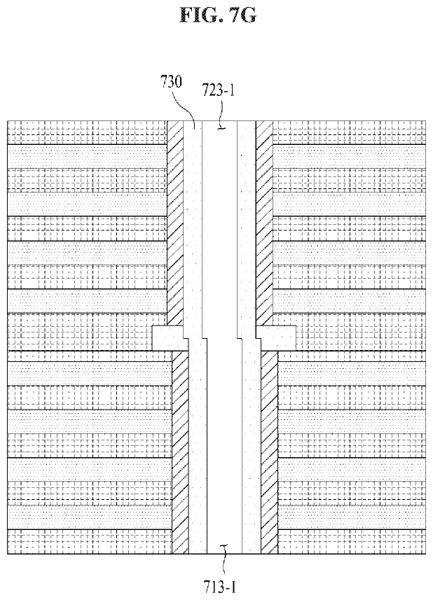

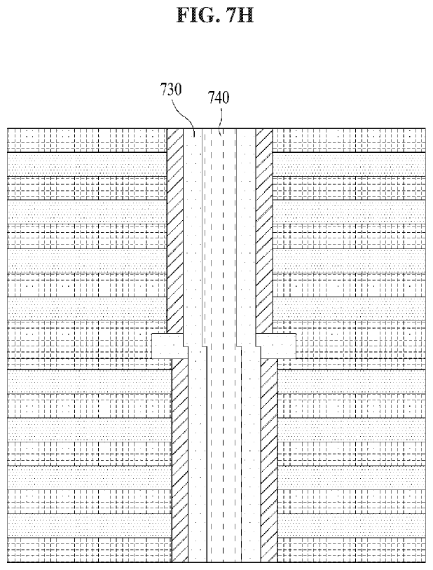

FIG. 6 is a flowchart showing a manufacturing method of a three-dimensional flash memory according to an embodiment. FIG. 7A to 7H are side cross-sectional views showing a three-dimensional flash memory to illustrate the manufacturing method of the three-dimensional flash memory as shown in FIG. 6. Hereinafter, a subject performing the manufacturing method as described below is an automated and mechanized manufacturing system, and the three-dimensional flash memory that has been manufactured through the manufacturing method may have the structure as shown in FIG. 4.

Referring to FIG. 6, in step S610, the manufacturing system may prepare a lower stack structure 710 as shown in FIG. 7A.

In this regard, the lower stack structure 710 may include a plurality of word lines 711 extending in the horizontal direction and stacked alternately with each other in the vertical direction, and at least one hole 712 extending vertically through the plurality of word lines 711.

Next, in step S620, the manufacturing system may form a charge storage layer 713 having an inner hole 713-1 defined therein in the at least one hole 712 of the lower stack structure 710, as shown in FIG. 7B.

In the above description, preparing the lower stack structure 710 and forming the charge storage layer 713 are set forth as separate steps.

However, the present disclosure is not limited or restricted thereto, and preparing the lower stack structure 710 and forming the charge storage layer 713 may be performed in one step. For example, in step S610, the lower stack structure 710 with the charge storage layer 713 including the inner hole 713-1 may be prepared, such that preparing the lower stack structure 710 and forming the charge storage layer 713 may be performed in one step.

Next, in step S630, the manufacturing system may dispose at least one buffer layer 714 on a tops surface of the lower stack structure 710, as shown in FIG. 7C. In more detail, the manufacturing system may form the at least one buffer layer 714 so as to have a size and a position set such that the at least one buffer layer 714 accommodates respective inner holes 713-1 and 723-1 of the lower stack structure 710 and an upper stack structure 720 in a plan view. That is, the manufacturing system may form the at least one buffer layer 714 so as to have a size and a position set such that the at least one buffer layer 714 accommodates both the inner hole 713-1 of the lower stack structure 710 and the inner hole 723-1 of the upper stack structure 720 to be formed in step S650, which will be described later in a plan view.

Furthermore, in step S630, the manufacturing system may form the at least one buffer layer 714 using the same material as a material constituting a channel layer 730 to be formed in step S670, which will be described later.

Next, in step S640, the manufacturing system may form the upper stack structure 720 on top of the lower stack structure 710 on which the at least one buffer layer 714 has been disposed, as shown in FIG. 7D.

Likewise, the upper stack structure 720 may include a plurality of word lines 721 extending in the horizontal direction and stacked alternately with each other in the vertical direction, and at least one hole 722 extending vertically through the plurality of word lines 721.

Next, in step S650, the manufacturing system may form a charge storage layer 723 having the inner hole 723-1 defined therein in the at least one hole 722 of the upper stack structure 720, as shown in FIG. 7E.

Next, in step S660, the manufacturing system may remove a portion of the at least one buffer layer 714 corresponding to the respective inner holes 713-1 and 723-1 of the lower stack structure 710 and the upper stack structure 720, as shown in FIG. 7F.

Then, in step S670, the manufacturing system may integratedly form the channel layer 730 in the respective inner holes 713-1 and 723-1 of the lower stack structure 710 and the upper stack structure 720 communicating with each other by removing the portion of the at least one buffer layer 714, as shown in FIG. 7G.

In this regard, the respective inner holes 713-1 and 723-1 of the lower stack structure 710 and the upper stack structure 720 may communicate with each other by removing the portion of the at least one buffer layer 714. Thus, the channel layer 730 may be formed in the integrated manner in the respective inner holes 713-1 and 723-1 of the lower stack structure 710 and the upper stack structure 720 communicating with each other. Thus, the poor connection between the lower and upper stack structures 710 and 720 may be prevented.

Furthermore, although not shown as a separate step, the manufacturing system may form a buried film 740 (e.g., oxide) in a hollow space of the channel layer 730, as shown in FIG. 7H, after step S670. However, the present disclosure is not limited or restricted thereto, and the channel layer 730 may be formed in a shape of a fully-solid cylinder in step S670, so that the process of forming the buried film 740 may be omitted.

Although the embodiments have been described above based on limited embodiments and drawings, various modifications and variations may be made from the above descriptions by those skilled in the art. For example, the described techniques may be performed in a different order than the described order, and/or, the components of the described system, structure, device, circuit, etc. may be combined with each other in a form different from the described form, or may be replaced with other components or equivalents, such that appropriate results may be achieved.

Therefore, other implementations, other embodiments, and equivalents to the claims fall within the scope of the claims as described below.

1. A three-dimensional flash memory with an improved stack connection, the three-dimensional flash memory comprising:
a plurality of stack structures, wherein each of the plurality of stack structures includes:
a plurality of word lines extending in a horizontal direction and stacked alternately with each other in a vertical direction; and
at least one cell string extending through the plurality of word lines in the vertical direction, wherein the at least one cell string includes a channel layer extending in the vertical direction and a charge storage layer formed to surround the channel layer; and
at least one buffer layer disposed between adjacent ones of the plurality of stack structures arranged in the vertical direction, wherein the least one buffer layer connects the respective channel layers of the adjacent ones of the plurality of stack structures to each other.

2. The three-dimensional flash memory of claim 1, wherein the at least one buffer layer has a size and a position set such that the at least one buffer layer accommodates both the respective channel layers of the adjacent ones of the plurality of stack structures in a plan view of the three-dimensional flash memory.

3. The three-dimensional flash memory of claim 1, wherein the at least one buffer layer is made of the same material as a material constituting the respective channel layers of the adjacent ones of the plurality of stack structures.

4. A method for manufacturing a three-dimensional flash memory with an improved stack connection, the method comprising:
preparing a lower stack structure including:
a plurality of word lines extending in a horizontal direction and stacked alternately with each other in a vertical direction; and
at least one hole extending through the plurality of word lines in the vertical direction;
forming a charge storage layer having an inner hole defined therein in the at least one hole of the lower stack structure;
disposing at least one buffer layer on a top surface of the lower stack structure;
forming an upper stack structure on top of the lower stack structure on which the at least one buffer layer has been disposed, wherein the upper stack structure including:
a plurality of word lines extending in the horizontal direction and stacked alternately with each other in the vertical direction; and
at least one hole extending through the plurality of word lines in the vertical direction;
forming a charge storage layer having an inner hole defined therein in the at least one hole of the upper stack structure;
removing a portion of the at least one buffer layer corresponding to the inner hole of each of the lower stack structure and the upper stack structure, wherein the inner hole of the lower stack structure and the inner hole of the upper stack structure communicate with each other by removing the portion of the at least one buffer layer; and
forming a channel layer in an integrated manner in the respective inner holes of the lower stack structure and the upper stack structure.

5. The method of claim 4, wherein the disposing of the at least one buffer layer includes forming the at least one buffer layer so as to have a size and a position set such that the at least one buffer layer accommodates both the respective inner holes of the lower stack structure and the upper stack structure in a plan view of the three-dimensional flash memory.
